(19) United States
(12) Patent Application Publication
(10) Pub. No.: US 2024/0021739 A1
(43) Pub. Date: Jan. 18, 2024

(54) INTERLOCKABLE AND SLIDABLE MODULE CLIP PIECE FOR MODULE PACKAGING

(71) Applicant: Maxeon Solar Pte. Ltd., Singapore (SG)

(72) Inventors: Jianxun Wu, Hubei Province (CN); Yafu Lin, Pleasanton, CA (US); Feldemar Batitis, Calamba City (PH); Yonggang Guo, Baoding, Hebei Province (CN)

(21) Appl. No.: 18/088,635

(22) Filed: Dec. 26, 2022

Related U.S. Application Data
(60) Provisional application No. 63/389,944, filed on Jul. 18, 2022.
(60) Provisional application No. 63/415,530, filed on Oct. 12, 2022.

(51) Int. Cl. H01L 31/02; B65D 67/02; B65D 81/05; B65D 57/00; B65D 85/48; B65D 71/00

(52) U.S. Cl. CPC H01L 31/02; B65D 67/02; B65D 81/057; B65D 57/006; B65D 85/48; B65D 71/00

(57) ABSTRACT

A module clip piece for a module is disclosed. The module clip piece includes at least one protrusion configured to engage at least one groove of a first neighboring module clip piece. The at least one protrusion protrudes in a first direction. At least one groove is coupled to the at least one protrusion and is configured to engage at least one protrusion of a second neighboring module clip piece. The at least one groove extends in a second direction that is orthogonal to the first direction.

### CROSS-REFERENCE TO RELATED APPLICATIONS

This application claims the benefit of U.S. Provisional Patent Application Ser. No. 63/389,944, filed Jul. 18, 2022, which is incorporated by reference herein in its entirety and of U.S. Provisional Patent Application Ser. No. 63/415,530, filed Oct. 12, 2022, which is incorporated by reference herein in its entirety.

### TECHNICAL FIELD

Embodiments of the disclosure pertain to clip pieces for solar panel modules, and more particularly, to interlockable and slidable module clip pieces for use in solar panel module packaging.

### BACKGROUND

The current packaging practice in the photovoltaic (PV) module industry is to use vertically packed modules to prevent micro-cracks that can be caused by vibration/shock during transport. During the packaging process, adjacent modules are separated by paper sleeves to protect the modules from scratches. Increasing concerns and/or complaints regarding this method have focused on specific challenges. For example, the susceptibility of the straps that are used to restrict the movement of the modules, to loosening, can result in package slanting/tilting, especially after long-distance shipping that can involve multiple transits. This presents a safety risk to customers as inadequately restricted modules are prone to movement that can cause injury. Another concern with vertically packed modules is that they can present challenges for subsequent partial package preparation. The challenges of vertically packed modules are especially evident with regard to residential project shipment, where the repacking of a partial quantity of modules is a common occurrence. A common complaint regarding residential project shipment relates to the difficulties that are encountered in vertically repacking a partial quantity of modules in a manner that is safe. Although partial quantities of modules can be horizontally repacked, the quantity of modules that can be packed is severely limited due to micro-cracks concerns.

### BRIEF DESCRIPTION OF THE DRAWINGS

FIG. 1A shows a plurality of vertically packed modules that are interlocked using vertically slidable corner pieces according to one embodiment.

FIG. 1B illustrates the relative positions of an exemplary set of four vertically slidable corner pieces with respect to modules such as the modules shown in FIG. 1A according to one embodiment.

FIG. 1C illustrates the vertical removal of a module from a plurality of vertically oriented modules that are connected by corner pieces according to one embodiment.

FIG. 1D shows a plurality of vertically oriented modules that are interlocked using horizontally slidable corner pieces for module packaging according to one embodiment.

FIG. 1E illustrates the relative positions of an exemplary set of four horizontally slidable corner pieces with respect to modules such as the modules shown in FIG. 1D according to one embodiment.

FIG. 1F illustrates the horizontal removal of a module from a plurality of vertically oriented modules connected by corner pieces according to one embodiment.

FIG. 1G shows the components of an exemplary corner piece according to one embodiment.

FIG. 1H shows the components of an exemplary corner piece according to one embodiment.

FIG. 1I shows the manner in which exemplary corner pieces fit together according to one embodiment.

FIG. 1J shows the manner in which an exemplary corner piece fits onto a module frame according to one embodiment.

FIG. 1K illustrates the vertical removal of vertically packed modules from a package in a manner that leaves the remaining vertically packed modules erect and stable according to one embodiment.

FIG. 1L shows a horizontal stack of modules that are fitted with corner pieces according to one embodiment.

FIG. 2A shows a plurality of vertically oriented modules that are interlocked using vertically slidable side pieces for module packaging according to one embodiment.

FIG. 2B shows a plurality of vertically oriented modules that are interlocked using horizontally slidable top/bottom pieces for module packaging according to one embodiment.

FIG. 2C is a perspective view showing features of an interlockable and slidable module clip piece according to one embodiment.

FIG. 2D is a perspective view showing features of an interlockable and slidable module clip piece according to one embodiment.

FIG. 3A shows protrusion and groove configurations for an exemplary corner piece according to one embodiment.

FIG. 3B shows protrusion and groove configurations for an exemplary corner piece according to one embodiment.

FIG. 3C shows protrusion and groove configurations for an exemplary corner piece according to one embodiment.

FIG. 3D shows protrusion and groove configurations for an exemplary corner piece according to one embodiment.

FIG. 3E shows protrusion and groove configurations for an exemplary corner piece according to one embodiment.

FIG. 3F shows protrusion and groove configurations for an exemplary corner piece according to one embodiment.

FIG. 4A shows protrusion and groove configurations for an exemplary side piece according to one embodiment.

FIG. 4B shows protrusion and groove configurations for an exemplary side piece according to one embodiment.

FIG. 4C shows protrusion and groove configurations for an exemplary side piece according to one embodiment.

FIG. 4D shows protrusion and groove configurations for an exemplary side piece according to one embodiment.

FIG. 4E shows protrusion and groove configurations for an exemplary side piece according to one embodiment.

FIG. 4F shows protrusion and groove configurations for an exemplary side piece according to one embodiment.

FIG. 5 shows a flowchart of a method of forming a module clip piece for a rectangular module according to one embodiment.

### DESCRIPTION OF THE EMBODIMENTS

In the following description, numerous specific details are set forth, in order to provide a thorough understanding of embodiments of the present disclosure. It will be apparent to one skilled in the art that embodiments of the present disclosure may be practiced without these specific details. In other instances, well-known features, are not described in detail in order to not unnecessarily obscure embodiments of the present disclosure. Furthermore, it is to be appreciated that the various embodiments shown in the Figures are illustrative representations and are not necessarily drawn to scale.

Certain terminology may also be used in the following description for the purpose of reference only, and thus is not intended to be limiting. For example, terms such as “upper”, “lower”, “above”, and “below” refer to directions in the drawings to which reference is made. Terms such as “top”, “center,” “front”, “back”, “rear”, and “side” describe the orientation and/or location of portions of the component within a consistent but arbitrary frame of reference which is made clear by reference to the text and the associated drawings describing the component under discussion. Such terminology may include the words specifically mentioned above, derivatives thereof, and words of similar import.

As used herein the term “package” is intended to refer to one or more modules that are bundled and/or boxed for storage or transit.

As used herein the term “packaging” is intended to refer to the act of creating a package of modules.

As used herein, the term “pack” is intended to refer to one or more vertically or horizontally placed modules. A pack of one module would include a single module vertically or horizontally disposed. A pack of two or more modules would comprise two or more either vertically or horizontally disposed modules for packaging.

As used herein the term “packing,” or, to “pack” is intended to refer to the act of placing one or more modules either vertically or horizontally together for packaging.

As used herein, the term “stack” is intended to refer to a pile of horizontally oriented modules that can be used in the preparation of a package. As used herein to “stack” is intended to refer to the act of piling a plurality of horizontally oriented modules for use in the preparation of a package.

As used herein the term “full quantity of modules” is intended to refer to the number of modules that is necessary to fill what is considered to be a full package of modules.

As used herein the term “partial quantity of modules” is intended to refer to a number of modules that is less than that which is necessary to fill what is considered to be a full package of modules.

As used herein the term “full package” of modules is intended to refer to a package of modules that contains the number of modules that is considered to completely fill the package of modules.

As used herein the term “partial package” of modules is intended to refer to a package of modules that contains a number of modules that is less than that which is considered to completely fill the package of modules.

As used herein the term “clip piece” or “module clip piece” is intended to refer to a device that can be firmly fastened or clipped to the frame of a module and which is interlockable with other module clip pieces.

As used herein the letter “V” indicates “vertically slidable” and used in conjunction with a number such as in “V101” refers to a vertically slidable structure (herein vertically slidable corner piece V101). As used herein the letter “H” indicates “horizontally slidable” and used in conjunction with a number such as in “H101” refers to a horizontally slidable structure (herein horizontally slidable corner piece H101). As used herein, a number enclosed by a parenthesis such as “(1)” refers to a position of a module clip piece on a module frame. Thus, as used herein a reference to V101(1) refers to the vertically slidable module clip piece that is located at position 1 on the module frame. As used herein, with regard to corner pieces “(1)” refers to the left top corner of a module, “(2)” refers to the right top corner of a module, “(3)” refers to the right bottom corner of a module, and “(4)” refers to the left bottom corner of a module. As used herein, as regards side pieces, “(1)” refers to the left side, and “(2)” refers to the right side. As used herein, as regards top/bottom pieces, “(1)” refers to the top, and “(2)” refers to the bottom. As used herein, subscripts refer to the position of a module frame among a plurality of module frames. Thus, as used herein a reference to V101(2)₂ refers to the vertically slidable module clip piece that is located at position 2 on the second module frame. In one embodiment, lower case letters that are used as a part of reference numbers herein refer to specific structural features of module clip pieces.

The current packaging practice in the photovoltaic (PV) module (hereinafter “module”) industry is to use vertically packed modules to prevent micro-cracks that can be caused by vibration/shock during transportation. During the packaging process, adjacent modules are separated by paper sleeves to protect the modules from scratches. Increasing concerns and/or complaints regarding this method have focused on specific challenges. For example, the susceptibility of the straps that are used to restrict the movement of the modules, to loosening, can result in package slanting/tilting, especially after long-distance shipping that can involve multiple transits of the packaged modules. This presents a safety risk to customers as inadequately restricted modules are prone to movement that can cause injury. Another concern with vertically packed modules is that they can present challenges for subsequent partial package preparation. The challenges of vertically packed modules are especially evident with regard to residential project shipment, where the repacking of a partial quantity of modules is a common occurrence. A common complaint regarding residential project shipment relates to the difficulties that are encountered in vertically repacking a partial quantity of modules in a manner that is safe. Although partial quantities of modules can be horizontally repacked, the quantity of modules that can be packed is severely limited due to micro-cracks concerns.

Moreover, using existing methodologies can result in the expenditure of a significant amount of money compensating customers for their losses and/or purchasing the extra material needed for adequately packaging partial quantities of modules. Efforts that have been made to improve existing methodologies include increasing the number of straps that are used to package modules, increasing the tensions of the straps that are used to package modules, and externally reinforcing wooden braces on packages. However, these measures have not proven satisfactory. For example, if the package strapping is excessively tight, it can help to prevent tilting, but can make the subsequent preparation of partial packages very difficult.

Approaches that overcome the challenges of such previous approaches are disclosed herein. As part of a disclosed embodiment, a module clip piece for a rectangular module is disclosed. The module clip piece includes at least one protrusion configured to engage at least one groove of a first neighboring module clip piece. The at least one protrusion protrudes in a first direction. At least one groove is coupled to the protrusion and is configured to engage at least one protrusion of a second neighboring module clip piece. The at least one groove extends in a second direction that is orthogonal to the first direction. In one embodiment, a plurality of modules can be fitted with the module clip pieces and then interlocked as part of the preparation of either a full or a partial package.

In one embodiment, because the interlocked module clip pieces prevent tilt when straps are not used, slanting/tilting, that can occur after long-distance shipping, such as involving multiple transits, is eliminated. In addition, in one embodiment, because modules can be maintained in a stable vertical orientation, even without the excessive strapping of previous approaches, the difficulties that are encountered in packing a partial quantity of modules in a manner that is safe and uncomplicated, are eliminated.

### Module Clip Pieces for Module Packaging

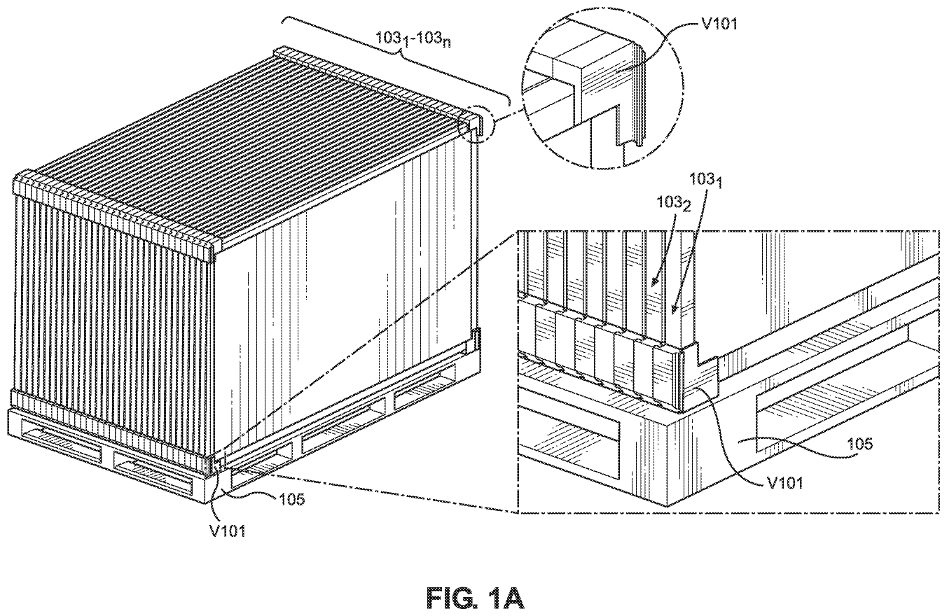

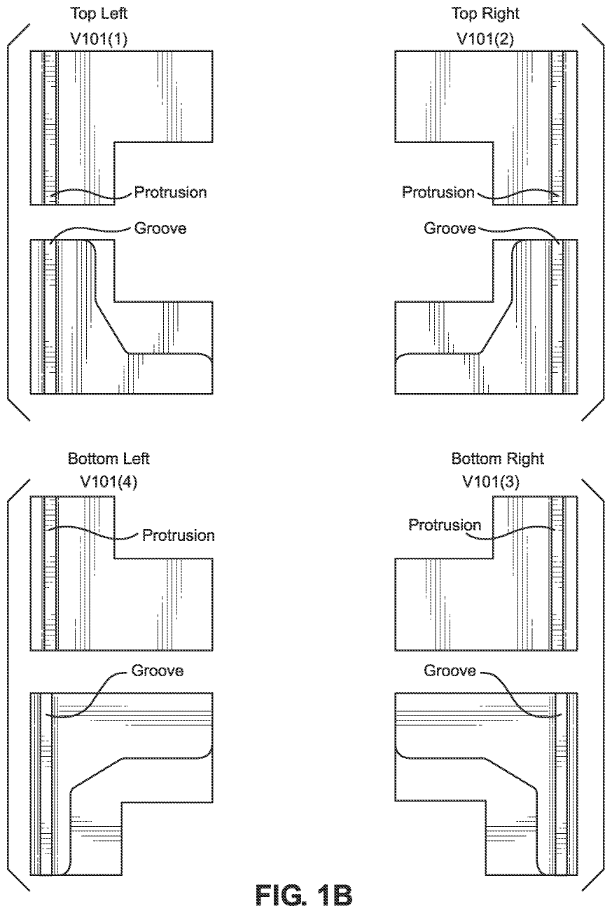

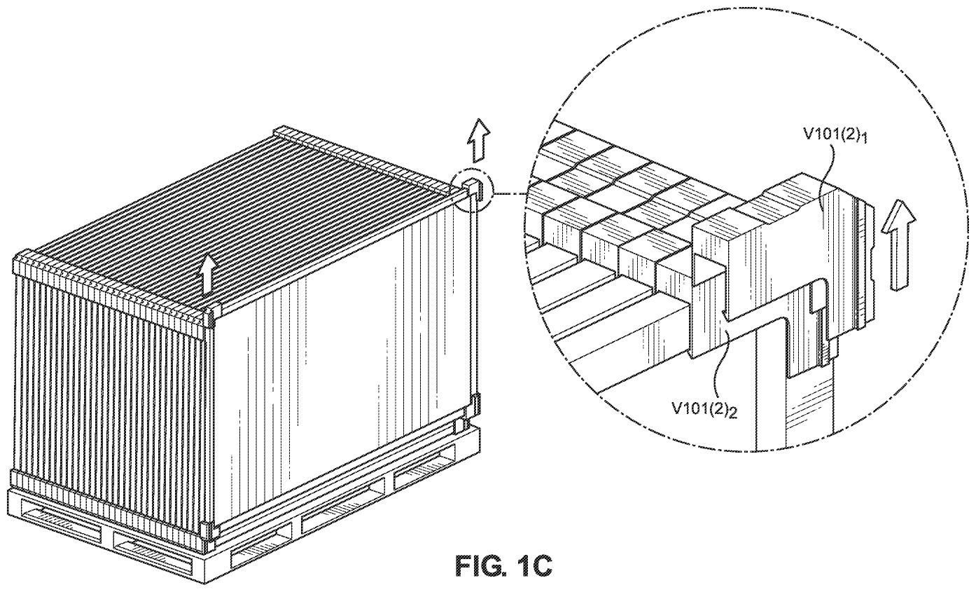

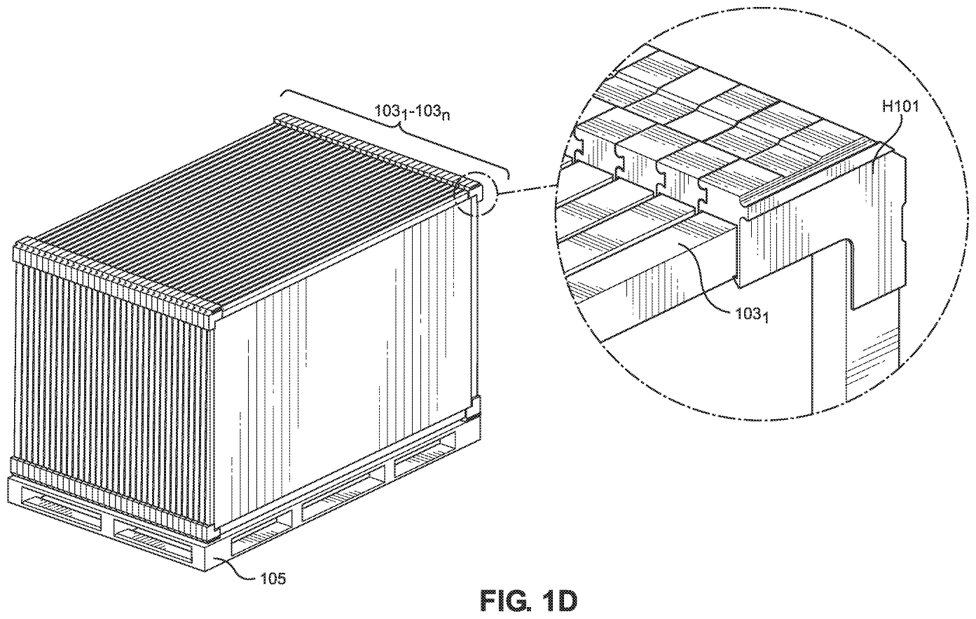

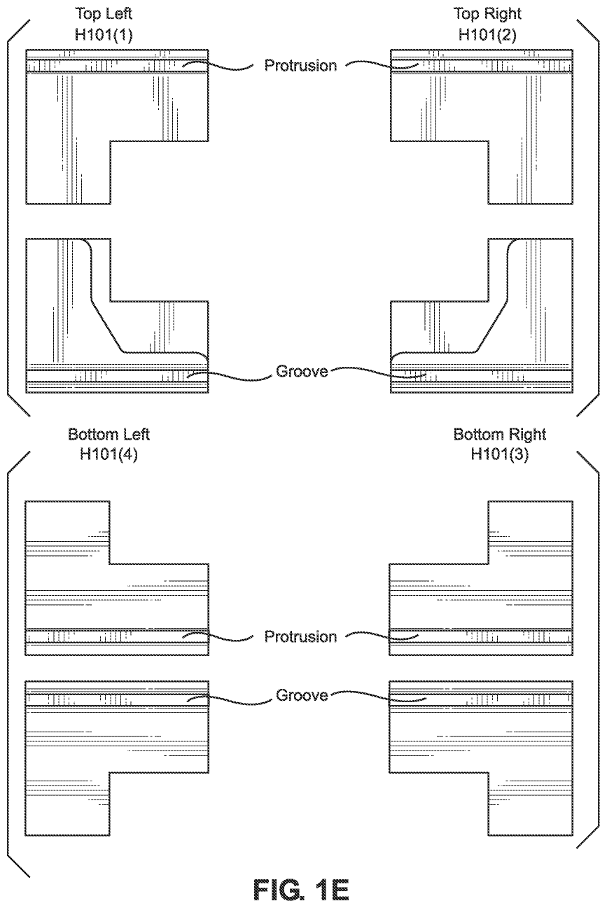

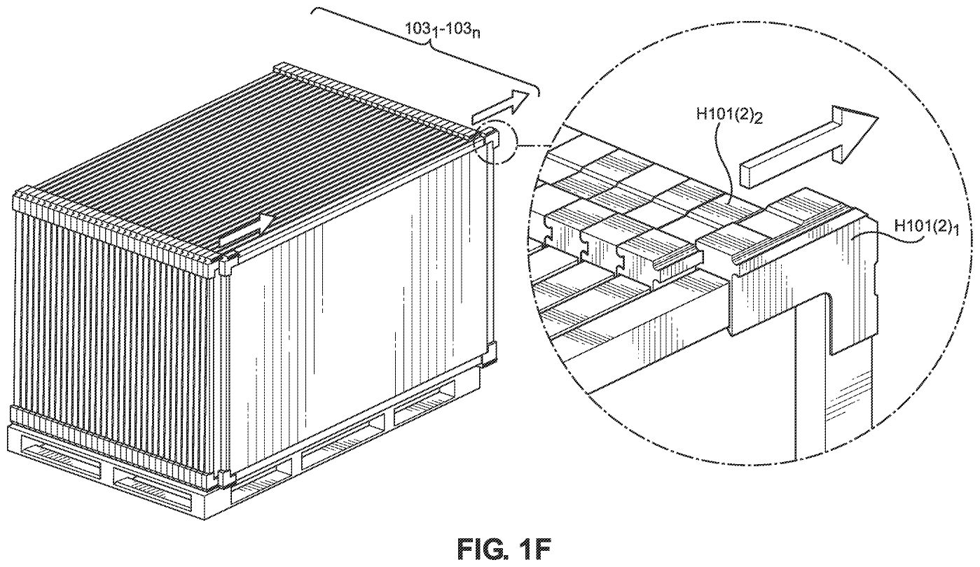

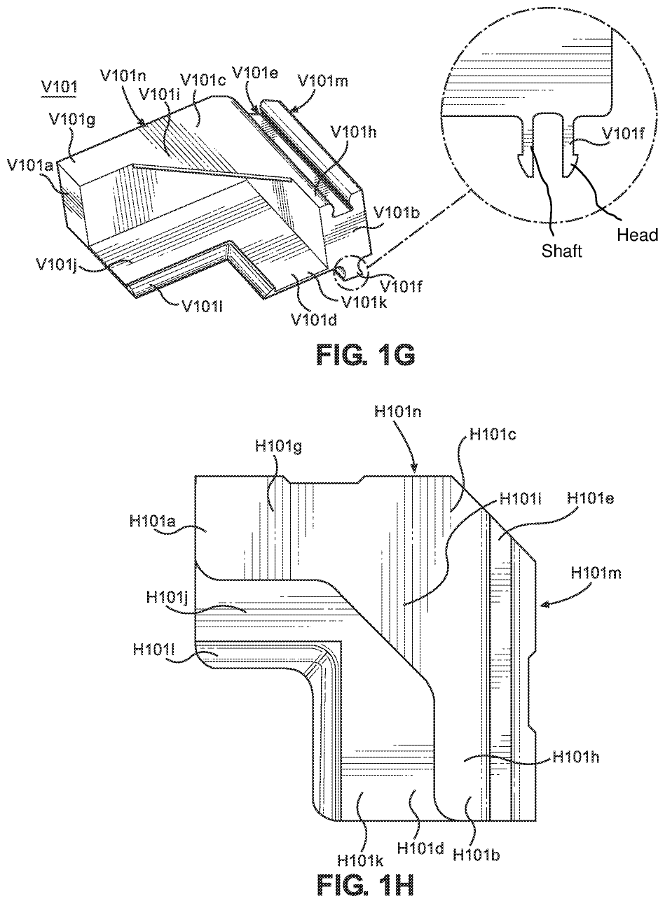

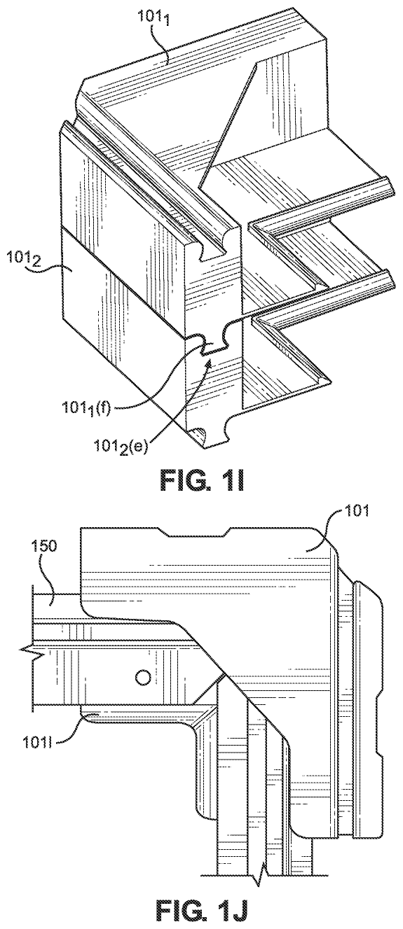

FIG. 1A shows a plurality of vertically oriented modules that are interlocked using vertically slidable corner pieces for module packaging according to one embodiment. FIG. 1A shows vertically slidable corner pieces V101 (V101 refers to all corner pieces in FIG. 1A), modules 103₁-103ₙ and pallet 105. In the FIG. 1A embodiment, a full quantity of modules 103₁-103ₙ, as can be used to prepare a full package of modules, is shown as being positioned on the pallet 105.

Referring to FIG. 1A, vertically slidable corner pieces V101 are attached to each corner of the plurality of vertically oriented modules 103₁-103ₙ. In one embodiment, vertically slidable corner pieces V101 include n sets of four corner pieces (with vertical oriented grooves and protrusions), that are associated with respective modules 103₁-103ₙ. Some of these corner pieces are not visible in FIG. 1A but have a design and utility that is similar to those that are shown. FIG. 1B illustrates the relative positions of an exemplary set of four vertically slidable corner pieces V101(1)-V101(4) with respect to modules such as respective modules 103₁-103ₙ shown in FIG. 1A. In addition, FIG. 1B shows sunny side and backsheet side profiles of each vertically slidable corner piece in the set of corner pieces. Referring to FIG. 1B, the sunny side profiles of the left top corner piece V101(1), right top corner piece V101(2), right bottom corner piece V101(3), and left bottom corner piece V101(4), are shown above the backsheet side profiles of the left top corner piece V101(1), right top corner piece V101(2), right bottom corner piece V101(3), and left bottom corner piece V101(4). Using the reference scheme of FIG. 1B, the set of four vertically slidable corner pieces V101 associated with each of the modules 103₁-103ₙ shown in FIG. 1A (including those that are not shown) are identified as V101(1-4)₁-V101(1-4)ₙ. In one embodiment, as shown in FIG. 1B, the corner pieces are designed to accommodate a frame that has top and bottom frame portions that are wider than its side frame portions. In other embodiments, the corner pieces can be designed to accommodate a frame with top, bottom and side frame portions that have other dimensional relationships. For example, frames that include top and bottom frame portions that are less wide than its side portions, or frames that include top, bottom and side portions of equal widths.

Referring again to FIG. 1A, the vertically slidable corner pieces V101 (e.g., V101(1-4)₁-V101(1-4)ₙ) of the individual modules are structured to interlock with the corresponding corner pieces of adjacent or neighboring modules. For example, as shown in FIG. 1A, a corner piece of module 103₁ interlocks with a corresponding corner piece of module 103₂ to interlock their associated modules together (see the FIG. 1A expanded view). Similarly, the corner pieces V101(1-4)₂-V101(1-4)ₙ of each successive module 103₂-103ₙ interlock with the corner pieces of their adjacent or neighboring module in a similar manner. In one embodiment, corner pieces V101(1-4)₁-V101(1-4)ₙ can be formed from plastic. In other embodiments, corner pieces V101(1-4)₁-V101(1-4)ₙ can be formed from other materials.

FIG. 1C illustrates the vertical removal of a module from a plurality of vertically oriented modules connected by corner pieces V101(1-4)₁-V101(1-4)ₙ according to one embodiment. In one embodiment, individual modules can be removed vertically but are prevented by snap fitted adjacent corner pieces (e.g., V101(2)₁-V101(2)₂) from moving horizontally or laterally. For example, referring to FIG. 1C, module 103₁ is enabled to be removed vertically because the four corner pieces V101(1-4)₁ that are associated with module 103₁ have vertically oriented grooves that are snap fitted onto the vertically oriented protrusions of corner pieces V101(1-4)₂ that are associated with module 103₂, along which module 103₁ is vertically slidable (illustrated in expanded view with corner pieces V101(2)₁ and V101(2)₂).

FIG. 1D shows a plurality of vertically oriented modules that are interlocked using horizontally slidable corner pieces for module packaging according to one embodiment. FIG. 1D shows horizontally slidable corner pieces H101, modules 103₁-103ₙ and pallet 105. In the FIG. 1D embodiment, a full quantity of modules 103₁-103ₙ as can be used to prepare a full package, is shown as being positioned on the pallet 105.

Referring to FIG. 1D, corner pieces H101 are attached to each corner of the plurality of vertically oriented modules 103₁-103ₙ. In one embodiment, corner pieces H101 include a plurality of sets of four corner pieces (with horizontal grooves and protrusions), that are associated with respective modules 103₁-103ₙ. Some of these corner pieces are not visible in FIG. 1D but have a design and utility that is similar to those that are shown. FIG. 1E illustrates the relative positions of an exemplary set of four corner pieces with respect to modules such as respective modules 103₁-103ₙ shown in FIG. 1D. In addition, FIG. 1E shows sunny side and backsheet side profiles of each corner piece in the set of corner pieces. Referring to FIG. 1E, the sunny side profiles of the left top corner piece H101(1), right top corner piece H101(2), right bottom corner piece H101(3), and left bottom corner piece H101(4) are shown above the backsheet profiles of the left top corner piece H101(1), right top corner piece H101(2), right bottom corner piece H101(3), and left bottom corner piece H101(4). Using this framework, the corner pieces 101 associated with each of the modules 103₁-103ₙ shown in FIG. 1D can be identified as H101(1-4)₁-H101(1-4)ₙ. In one embodiment, as shown in FIG. 1E, the corner pieces are designed to accommodate a frame that has top and bottom frame portions that are wider than its side frame portions. In other embodiments, the corner pieces can be designed to accommodate a frame with top, bottom and side frame portions that have other dimensional relationships. For example, frames that include top and bottom frame portions that are less wide than its side portions, or frames that include top, bottom and side portions of equal widths.

Referring again to FIG. 1D, the horizontally slidable corner pieces H101 (e.g., H101(1-4)₁-H101(1-4)ₙ) of the individual modules are designed to interlock with the corresponding corner pieces of adjacent or neighboring modules. For example, as shown in FIG. 1D, a corner piece of module 103₁ interlocks with a corresponding corner piece of module 103₂ to interlock their associated modules together (see the FIG. 1D expanded view). Similarly, the corner pieces H101(1-4)₂-H101(1-4)ₙ of each successive module 102₂-102ₙ interlock with the corner pieces of their adjacent or neighboring module in the same manner. In one embodiment, corner pieces H101(1-4)₁-H101(1-4)ₙ can be formed from plastic. In other embodiments, corner pieces H101(1-4)₁-H101(1-4)ₙ can be formed from other materials.

FIG. 1F illustrates the horizontal removal of a module from a plurality of vertically oriented modules connected by corner pieces H101(1-4)₁-H101(1-4)ₙ according to one embodiment. In one embodiment, individual modules can be removed horizontally but are prevented by snap fitted adjacent corner pieces from moving vertically or laterally. For example, referring to FIG. 1F, module 103₁ is enabled to be removed horizontally because the four corner pieces H101(1-4)₁ that are associated with module 103₁, have horizontally oriented grooves that are snap fitted onto the horizontally oriented protrusions of corner pieces H101(1-4)₂ that are associated with module 103₂, along which module 103₁ is horizontally slidable (illustrated in expanded view with corner pieces H101(2)₁ and H101(2)₂).

It should be appreciated that in embodiments where the width of the top portion of a module frame is the same as the width of the side portions of the module frame (at least on the sunny side of the module), which is different from the module frame of the embodiments of FIGS. 1A-1F, the set of corner pieces that are attached to the module frame can be rotated by one position either clockwise or counterclockwise relative to the module to change the slidable direction of the set of corner pieces from vertically slidable to horizontally slidable or vice versa.

FIG. 1G shows the components of an exemplary corner piece V101 according to one embodiment. In one embodiment, the exemplary corner piece V101 is a vertically slidable module clip that can be used, as described with reference to FIG. 1B, at locations V101(1) (upper left corner) and V101(3) (bottom right corner) of a module. Referring to FIG. 1G, in one embodiment, the corner piece V101 includes, orthogonal first L-angle portion V101a and second L-angle portion V101b (that together form an L shaped profile), and first sidewall structure V101c and second sidewall structure V101d that extend between respective sides of the first L-angle portion V101a and the second L-angle portion V101b. The second L-angle portion V101b includes a groove V101e that is formed in the side of the second L-angle portion V101b that is adjacent to the outside surface of the first sidewall structure V101c and a protrusion V101f that extends from the side of the second L-angle portion V101b that is adjacent to the outside surface of the second sidewall structure V101d. In one embodiment, as shown in FIG. 1G, the first sidewall structure V101c includes first V101g and second V101h orthogonally oriented portions. In one embodiment, the first V101g and the second V101h orthogonally oriented portions can include rounded corners (not shown in the FIG. 1G example corner piece V101) and a diagonally oriented straight edged region V101i formed between the first V101g and the second V101h orthogonally oriented portions. In one embodiment, the second sidewall structure V101d has an L-shaped perimeter profile. In one embodiment, the second sidewall structure V101d can include first V101j and second V101k orthogonally oriented portions and a ridge V101 formed on its inner surface along a central portion of its outer edge. In one embodiment, the second sidewall structure V101d can include rounded corners (not shown in the FIG. 1G example corner piece). In one embodiment, the ridge V101l can be beveled. In other embodiments, the ridge V101l may not be beveled and can have other shapes and/or geometries.

Referring again to FIG. 1G, in one embodiment, the first L-angle portion V101a extends a distance between 91 and 92 mm from a first backside surface V101m of the corner piece V101. In other embodiments, the first L-angle portion V101a can extend other distances from the first backside surface V101m of the corner piece V101. In one embodiment, the second L-angle portion V101b extends a distance between 91 and 92 mm from a second backside surface V101n of the corner piece V101. In other embodiments, the second L-angle portion V101b can extend other distances from the second backside surface V101n of the corner piece V101. In one embodiment, the first orthogonally oriented portion V101g of first sidewall structure V101c extends a distance of 27.6 mm from the second backside surface V101n of the corner piece V101. In other embodiments, the first orthogonally oriented portion V101g of first sidewall structure V101c can extend other distances form the second backside surface V101n of the corner piece V101. In one embodiment, the second orthogonally oriented portion V101h of first sidewall structure V101c extends a distance of 27.6 mm from the first backside surface V101m of the corner piece V101. In other embodiments, the second orthogonally oriented portion V101h of first sidewall structure V101c can extend other distances from the first backside surface V101m of the corner piece V101.

In one embodiment, the first orthogonally oriented portion V101j of second sidewall structure V101d extends a distance of 59.9 mm from the second backside surface V101n of the corner piece V101. In other embodiments, the first orthogonally oriented portion V101j of second sidewall structure V101d can extend other distances form the second backside surface V101n of the corner piece V101. In one embodiment, the second orthogonally oriented portion V101k of second sidewall structure V101d extends a distance of 50.5 mm from the first backside surface V101m of the corner piece V101. In other embodiments, the second orthogonally oriented portion V101k of second sidewall structure V101d can extend other distances form the first backside surface V101m of the corner piece V101.

Referring again to FIG. 1G, in one embodiment, the groove V101e can extend a distance between 7.85 and 8.15 mm into a surface of the second L-angle portion V101b that is adjacent the outer surface of the first sidewall structure V101c. In other embodiments, the groove V101e can extend other distances into the surface of the second L-angle portion V101b that is adjacent the outer surface of the first sidewall structure V101c. In one embodiment, the groove V101e can have an undercut region that accommodates the shape of the top portion of a protrusion similar to that of V101f to facilitate the firm interlock of the corner piece V101 to a neighboring corner piece. In other embodiments, the groove V101e can have any shape or geometry that engages a protrusion of a neighboring corner piece in a manner that prevents movement of the protrusion in a first direction that laterally separates the respective corner pieces that are associated with the groove V101e and the protrusion but allows the protrusion to be freely moved along the groove V101e in a second direction that is orthogonal to the first direction. In one embodiment, the protrusion V101f can extend a distance between 7.55 and 7.85 mm from the side of the second L-angle portion V101b that is adjacent the outer surface of the second sidewall structure V101d. In other embodiments, the protrusion V101f can extend other distances from the side of the second L-angle portion V101b that is adjacent the outer surface of the second sidewall structure V101d. In one embodiment, the protrusion V101f can have a top portion formed to fit an undercut region of a groove of neighboring corner pieces to facilitate the interlock of the corner piece V101 to neighboring corner pieces. In other embodiments, the protrusion V101f can have a top portion that has any shape or geometry that can engage a groove of a neighboring corner piece in a manner that prevents movement of the protrusion V101f in a first direction that laterally separates the respective corner pieces that are associated with the protrusion V101f and the groove of the neighboring corner piece, but allows the protrusion V101f to be freely moved along the groove in a second direction that is orthogonal to the first direction.

FIG. 1H shows the components of an exemplary corner piece H101 according to one embodiment. In one embodiment, the exemplary corner piece H101 is a horizontally slidable module clip piece that can be used, as described with reference to FIG. 1B, at locations H101(2) (upper right corner) and H101(4) (bottom left corner) of a module. Referring to FIG. 1H, in one embodiment, the corner piece H101 includes, orthogonal first L-angle portion H101a, and second L-angle portion H101b (that together form an L shaped profile), and first sidewall structure H101c and second sidewall structure H101d, that extend between respective sides of the first L-angle portion H101a, and the second L-angle portion H101b. The second L-angle portion H101b, includes a groove H101e, that is formed in the side of the second L-angle portion H101b, that is adjacent to the outside surface of the first sidewall structure H101c, and a protrusion H101f, that extends from the side of the second L-angle portion H101b, that is adjacent to the outside surface of the second sidewall structure H101d. In one embodiment, as shown in FIG. 1H, the first sidewall structure H101c has a perimeter geometry that includes first H101g and second H101h orthogonally oriented portions with rounded corners and a diagonally oriented straight edged region H101i formed between the first H101g and the second H101h orthogonally oriented portions. In one embodiment, the second sidewall structure H101d has an L-shaped perimeter profile with rounded corners that includes first H101j and second H101k orthogonally oriented portions and a ridge H101l formed on its inner surface along a central portion of its outer edge. In one embodiment, the ridge H101l can be beveled. In other embodiments, the ridge H101l may not be beveled and can have other shapes and/or geometries.

Referring again to FIG. 1H, in one embodiment, the first L-angle portion H101a extends a distance between 91 and 92 mm from a first backside surface 101m of the corner piece H101. In other embodiments, the first L-angle portion H101a can extend other distances from the first backside surface H101m of the corner piece H101. In one embodiment, the second L-angle portion H101b extends a distance between 91 and 92 mm from a second backside surface H101n of the corner piece H101. In other embodiments, the second L-angle portion H101b can extend other distances from the second backside surface H101n of the corner piece H101. In one embodiment, the first orthogonally oriented portion H101g of the first sidewall structure H101c extends a distance of 27.6 mm from the second backside surface H101n of the corner piece H101. In other embodiments, the first orthogonally oriented portion H101g of the first sidewall structure H101c can extend other distances form the second backside surface H101n of the corner piece H101. In one embodiment, the second orthogonally oriented portion H101h of first sidewall structure H101c extends a distance of 27.6 mm from the first backside surface H101m of the corner piece H101. In other embodiments, the second orthogonally oriented portion H101h of first sidewall structure H101c can extend other distances from the first backside surface H101m of the corner piece H101.

In one embodiment, as regards horizontally slidable corner piece H101, the first orthogonally oriented portion H101j of second sidewall structure H101d extends a distance of 50.5 mm from the second backside surface H101n of the corner piece H101. In other embodiments, as regards horizontally slidable corner piece H101, the first orthogonally oriented portion H101j of second sidewall structure H101d can extend other distances form the second backside surface H101n of the corner piece H101. In one embodiment, as regards horizontally slidable corner piece H101, the second orthogonally oriented portion H101k of second sidewall structure H101d extends a distance of 59.9 from the first backside surface H101m of the corner piece H101. In other embodiments, as regards horizontally slidable corner piece H101, the second orthogonally oriented portion H101k of second sidewall structure H101d can extend other distances form the first backside surface H101m of the corner piece H101.

Referring again to FIG. 1H, in one embodiment, the groove H101e can extend a distance between 7.85 and 8.15 mm into a surface of the second L-angle portion H101b that is adjacent the outer surface of the first sidewall structure H101c. In other embodiments, the groove H101e can extend other distances into the surface of the second L-angle portion H101b that is adjacent the outer surface of the first sidewall structure H101c. In one embodiment, the groove H101e can have an undercut region that accommodates the shape of the top portion of the protrusion of a neighboring corner piece to facilitate the firm interlock of corner piece H101 to a neighboring corner piece. In other embodiments, the groove H101e can have any shape or geometry that engages a protrusion of a neighboring corner piece in a manner that prevents movement of the protrusion in a first direction that laterally separates the respective corner pieces that are associated with the groove H101e and the protrusion of the neighboring corner piece but allows the protrusion to be freely moved along the groove H101e in a second direction that is orthogonal to the first direction. In one embodiment, the protrusion of corner piece H101 (not shown in FIG. 1H) can extend a distance between 7.55 and 7.85 mm from the side of the second L-angle portion H101b that is adjacent the outer surface of the second sidewall structure H101d. In other embodiments, the protrusion can extend other distances from the side of the second L-angle portion H101b that is adjacent the outer surface of the second sidewall structure H101d. In one embodiment, the protrusion can have a top portion formed to fit an undercut region of a groove of a neighboring corner piece to facilitate the interlock of the corner piece H101 to the neighboring corner piece. In other embodiments, the protrusion can have a top portion that has any shape or geometry that can engage a groove of a neighboring corner piece in a manner that prevents movement of the protrusion in a first direction that laterally separates the respective corner pieces that are associated with the protrusion and the groove, but allows the protrusion to be freely moved along the groove in a second direction that is orthogonal to the first direction.

FIG. 1I shows the manner in which exemplary corner pieces 101₁ and 101₂ fit together according to one embodiment. In the FIG. 1I embodiment, the corner piece 101₁ includes protrusion 101₁(f) and the corner piece 101₂ includes groove 101₂(e). Referring to FIG. 1I, the protrusion 101₁(f) of the corner piece 101₁ and the groove 101₂(e) of the corner piece 101₂ are shown as interlocked. In one embodiment, the protrusion 101₁(f) of the corner piece 101₁ and the groove 101₂(e) of the corner piece 101₂ can be caused to interlock by snap fitting. In one embodiment, the protrusion 101₁(f) and the groove 101₂(e) can be caused to snap fit together through operation of gravity on the module and/or through a pushing together of the corner pieces 101₁ and 101₂. In one embodiment, when the protrusion 101₁(f) and the groove 101₂(e) are snap fitted together, movement of the corner piece 101₁ in the direction orthogonal to the direction in which the groove 101₂(e) extends is prevented. However, movement of the corner piece 101₁ in the direction in which the groove 101₂(e) extends is enabled to be carried out freely. In the FIG. 1I embodiment, exemplary corner pieces are designed to fit onto the frame of a module such that the protrusions and grooves of the corner pieces are vertically oriented. However, in other embodiments, the exemplary corner pieces can be designed to fit onto the frame of a module such that the protrusions and grooves of the corner pieces are horizontally oriented.

FIG. 1J shows the manner in which an exemplary corner piece fits onto a module frame 150 according to one embodiment. In FIG. 1J, corner piece 101 includes a ridge 101₁ that is configured to help securely accommodate and attach the module frame 150. In one embodiment, when all four corners of the module frame 150 is fitted with the corner piece 101, other module frames that are similarly fitted can be interlocked in the manner shown in FIG. 1A. In the FIG. 1J embodiment, corner piece 101 is designed to fit onto the frame of a module such that the protrusions and grooves of the corner pieces are vertically oriented. However, in other embodiments, exemplary corner pieces can be designed to fit onto the frame of a module such that the protrusions and grooves of the corner pieces are horizontally oriented.

FIG. 1K illustrates the vertical removal of vertically packed modules 103₁-103n from a package in a manner that leaves the remaining vertically packed modules erect and stable and enables an uncomplicated repack of the partial quantity of modules that remain according to one embodiment. In FIG. 1K, a plurality of modules is shown as being situated inside of a carton 160. In one embodiment, the carton 160 can be a part of package that does not include strapping. In other embodiments, the carton 160 can be a part of a package that includes strapping. Referring to FIG. 1F, because of the stable package structure provided by the corner pieces 101, modules can be pulled from the package (out of the carton 160) vertically without a support structure upon which to lean the modules that remain. In one embodiment, because modules can be pulled out vertically, unpacking the entire package to remove individual modules, is unnecessary. Moreover, because the modules are erect and stable, there are no safety concerns from leaning/tilting and unstable modules. In the FIG. 1K embodiment, the exposure of the top of the vertically packed modules in the carton 160 enables a vertical removal of vertically packed modules 103₁-103n. However, in other embodiments, where horizontally slidable corner pieces are being used, an exposure of the sides of vertically packed modules 103₁-103n in the carton 160 can enable horizontal removal of vertically packed modules 103₁-103n.

FIG. 1L shows a horizontal stack 170 of modules that are fitted with corner pieces 101 according to one embodiment. In one embodiment, when modules are horizontally packed, during transport of the modules, the corner piece framework separates the modules and transfers the shock and stress through the interlocked corner pieces 101, to the pallet 105 instead of the lower most module. Moreover, because the shock and stress encountered during the transport of horizontally packed modules is directed away from the packed modules, there is less concern about damaging the packed modules and the number of modules that can be packed for transport can be safely increased. In one embodiment, the use of the corner pieces 101 enables up to 30 modules to be horizontally packed. In other embodiments, the use of the corner pieces 101 may enable greater than 30 modules to be horizontally packed. In one embodiment, for partial packages prepared at regional warehouses, using the corner pieces 101 increases delivery capacity as more modules can be horizontally packed and delivered to customers. In the FIG. 1L embodiment, the corner pieces having vertically oriented (coincident with top to bottom direction of the module) protrusions and grooves enable horizontally packed modules to be removed in the direction in which the top (or bottom) of the module frame points. In the FIG. 1L embodiment, where corner pieces with horizontally oriented protrusions and grooves are used, horizontally packed modules can be removed in the directions in which the sides of the module frame point.

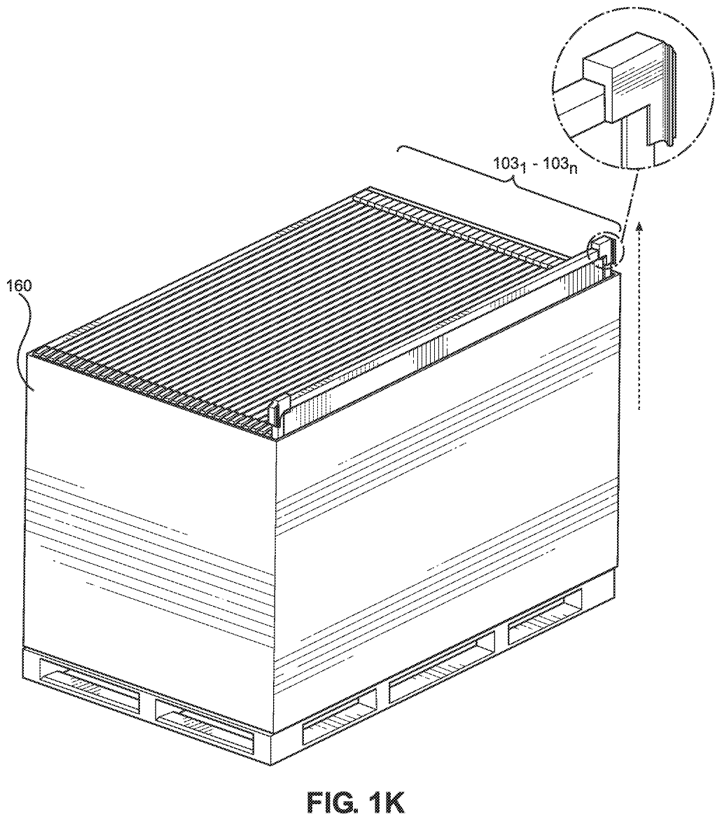

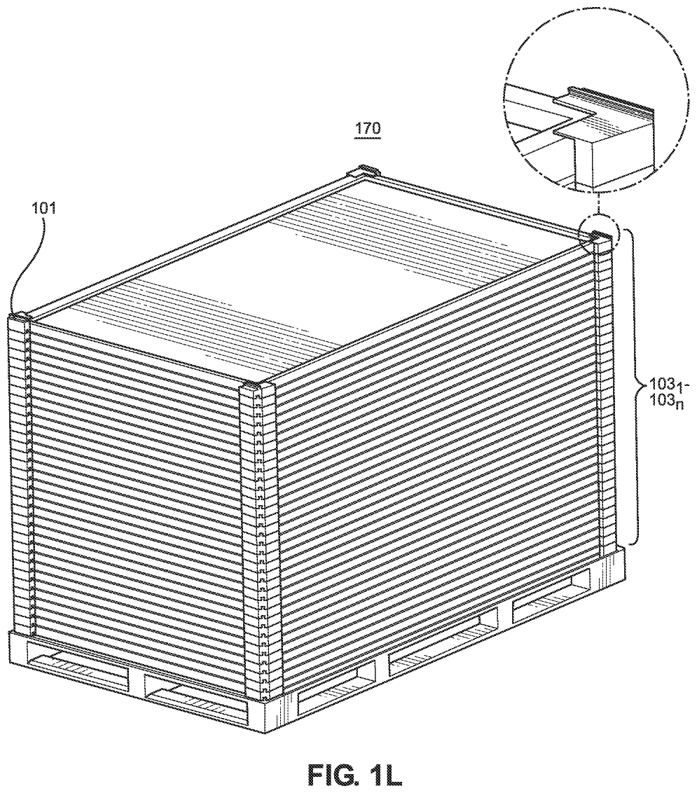

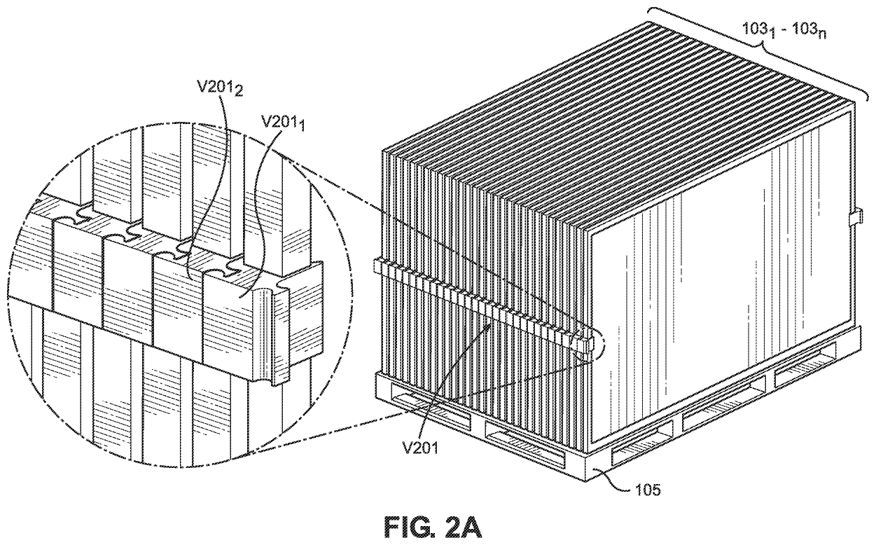

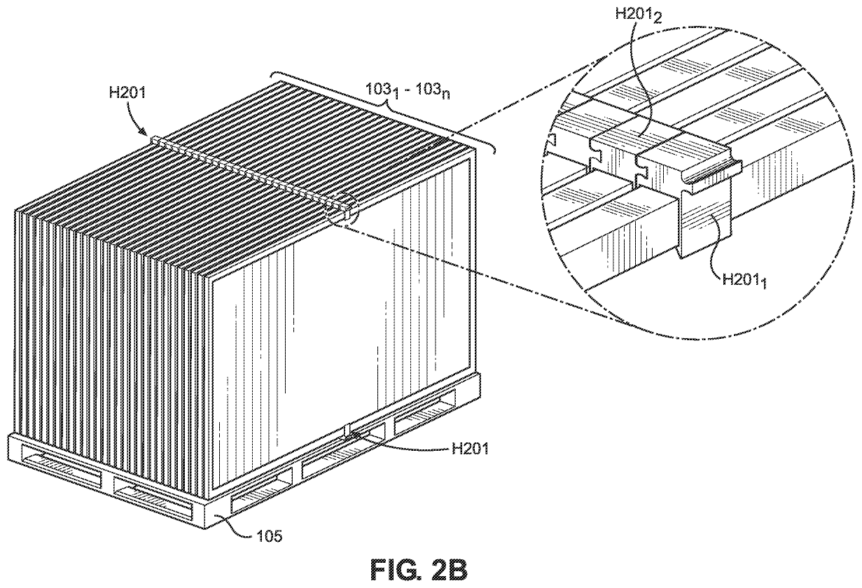

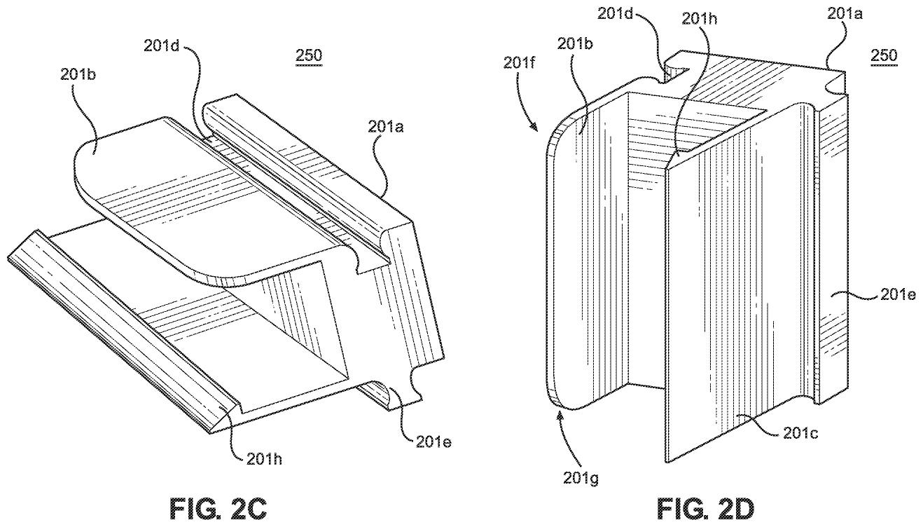

FIG. 2A shows a plurality of vertically oriented modules that are interlocked using vertically slidable side pieces for module packaging according to one embodiment. FIG. 2A shows vertically slidable side pieces V201, modules 103₁-103ₙ and pallet 105. In the FIG. 2A embodiment, a full quantity of modules 103₁-103ₙ as can be used to prepare a full package, is shown as being positioned on the pallet 105.

Referring to FIG. 2A, vertically slidable side pieces V201 are attached to each side of the plurality of vertically oriented modules 103₁-103ₙ. In one embodiment, the vertically slidable side pieces V201 of the individual modules are structured to interlock with the corresponding vertically slidable side pieces of adjacent or neighboring modules. For example, as shown in FIG. 2A, a vertically slidable side piece V201i of module 103₁ interlocks with a corresponding vertically slidable side piece V201₂ of module 103₂ to interlock their associated modules together (see the FIG. 2A expanded view). Similarly, the vertically slidable side pieces V201₃-V201ₙ of each successive module 103₃-103ₙ interlock with the vertically slidable side pieces of their adjacent or neighboring module(s) in the same manner. In one embodiment, the vertically slidable side pieces V201 can be formed from plastic. In other embodiments, vertically slidable side pieces V201 can be formed from other materials.

Referring to FIG. 2A, individual modules such as module 103₁ can be removed vertically even though they are prevented from moving horizontally or laterally. For example, vertically slidable side pieces V201₁ and V201₂ with their vertically mated groove and protrusion help enable module 103₁ to be removed vertically, while preventing module 103₁ from moving horizontally or laterally (because it is snap fitted in a stable vertical orientation).

FIG. 2B shows a plurality of vertically oriented modules that are interlocked using horizontally slidable top/bottom pieces for module packaging according to one embodiment. FIG. 2B shows horizontally slidable top/bottom pieces H201, modules 103₁-103ₙ and pallet 105. In the FIG. 2B embodiment, a full quantity of modules 103₁-103ₙ as can be used to prepare a full package, is shown as being positioned on the pallet 105.

Referring to FIG. 2B, horizontally slidable top/bottom pieces H201 are attached to the top and the bottom parts of the frames of the plurality of vertically oriented modules 103₁-103ₙ. In one embodiment, the horizontally slidable top/bottom pieces H201 of the individual modules are structured to interlock with the corresponding top/bottom pieces of adjacent or neighboring modules. For example, as shown in FIG. 2B, a horizontally slidable top piece H201₁ of module 103₁ interlocks with a horizontally slidable top piece H201₂ of module 103₂ to interlock their associated modules together (see the FIG. 2A expanded view). Similarly, the horizontally slidable top/bottom pieces H201₃-H201ₙ of each successive module interlock with their adjacent or neighboring module(s) in the same manner. In one embodiment, horizontally slidable top/bottom pieces H201 can be formed from plastic. In other embodiments, horizontally slidable top/bottom pieces H201 can be formed from other materials.

Referring again to FIG. 2B, individual modules such as module 103₁ can be removed horizontally even though they are prevented from moving vertically or laterally. For example, horizontally slidable top pieces H201₁ and H201₂, with their horizontally mated groove and protrusion enable module 103₁ to be removed horizontally, while preventing module 103₁ from moving vertically or laterally. Thus, slidable top pieces H201₁ and H201₂ snap fit together to help maintain module 103₁ in a stable, vertically oriented and horizontally slidable position.

FIG. 2C and FIG. 2D are perspective views showing features of a slidable and interlockable module clip piece 250 that is representative of both the vertically slidable side piece V201 and the horizontally slidable top/bottom piece H201 of FIG. 2A and FIG. 2B which can share similar features according to one embodiment. In one embodiment, differences and/or similarities in dimension of a particular feature can be based on the dimensions of the associated module frame. Referring to FIG. 2C, in one embodiment, module clip piece 250 includes a base 201a, and a first sidewall structure 201b and a second sidewall structure 201c that extend from the sides of the base 201a. The base 201a includes a groove 201d that is formed in the side of the base 201a that is adjacent to the outside surface of the first sidewall structure 201b and a protrusion 201e that extends from the side of the base 201a that is adjacent to the outside surface of the second sidewall structure 201c. In one embodiment, as shown in FIG. 2D, the first sidewall structure 201b has a perimeter geometry that includes first 201f and second 201g rounded corners. In one embodiment, the second sidewall structure 201c has a ridge 201h formed on its inner surface along its outer edge. In one embodiment, the ridge 201h can be beveled. In other embodiments, the ridge 201h may not be beveled and can have other shapes and/or geometries.

Referring again to FIGS. 2C and 2D, in one embodiment, the base 201a is between 91 and 92 mm in length. In other embodiments, the base 201a can have other lengths. In one embodiment, the first sidewall structure 201b extends a distance of 27.6 mm from a backside surface 201i of the base 201a of module clip piece 250. In other embodiments, the first sidewall structure 201b can extend other distances from the backside surface 201i of the base 201a of module clip piece 250.

In one embodiment, as regards side pieces, the second sidewall structure 201c extends a distance of 50.5 mm from the backside surface 201i of the base 201a of module clip piece 250. In other embodiments, as regards side pieces, the second sidewall structure 201c can extend other distances form the backside surface 201i of the module clip piece 250. In one embodiment, as regards top/bottom pieces, the second sidewall structure 201c extends a distance of 59.9 mm from the backside surface 201i of the base 201a of module clip piece 250. In other embodiments, as regards top/bottom pieces, the second sidewall structure 201c can extend other distances form the backside surface 201i of the module clip piece 250.

Referring again to FIGS. 2C and 2D, in one embodiment, the groove 201d can extend a distance between 7.85 and 8.15 mm into a surface of the base 201a that is adjacent the outer surface of the first sidewall structure 201b. In other embodiments, the groove 201d can extend other distances into the surface of the base 201a that is adjacent the outer surface of the first sidewall structure 201b. In one embodiment, the groove 201d can have an undercut region that accommodates the shape of the top portion of a protrusion to facilitate the firm interlock of the associated module clip piece to a neighboring module clip piece. In one embodiment, the groove 201d can have any shape or geometry that engages a protrusion of a neighboring module clip piece in a manner that prevents movement of the protrusion in a first direction that laterally separates the respective module clip piece that is associated with the groove 201d and the module clip piece that is associated with the protrusion but allows the protrusion to be freely moved along the groove 201d in a second direction that is orthogonal to the first direction. In one embodiment, the protrusion 201e can extend a distance between 7.55 and 7.85 mm from the side of the base 201a that is adjacent the outer surface of the second sidewall structure 201c. In other embodiments, the protrusion 201e can extend other distances from the side of the base 201a that is adjacent the outer surface of the second sidewall structure 201c. In one embodiment, the protrusion 201e can have a top portion formed to fit an undercut region of a groove of neighboring module clip pieces to facilitate interlock of the module clip piece 250 to a neighboring module clip piece. In one embodiment, the protrusion 201e can have a top portion that has any shape or geometry that can engage a groove of a neighboring module clip piece in a manner that prevents movement of the protrusion 201e in a first direction that laterally separates the respective module clip pieces that are associated with the protrusion 201e and the groove, but allows the protrusion 201e to be freely moved along the groove in a second direction that is orthogonal to the first direction.

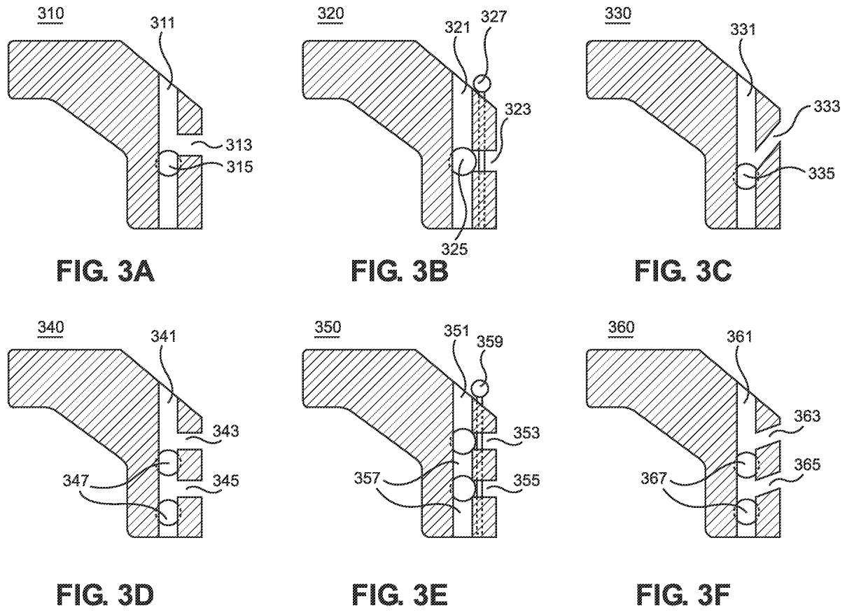

FIGS. 3A-3F show additional protrusion and groove configurations for exemplary corner pieces according to one embodiment. In one embodiment, the corner pieces shown in FIGS. 3A-3F can be used on a single side of a module to provide a measure of package stability (such as for transport that is not lengthy), or in the case of the corner pieces shown in FIGS. 3B and 3E, in combination with other either vertically or horizontally slidable corner pieces, to enhance package stability. In FIGS. 3A-3F, a circular representation of a protrusion, that is associated with an adjacent and interlocked corner piece (other parts of the adjacent and interlocked corner piece are not shown) is superimposed on the diagrams of the exemplary corner pieces. Referring to FIG. 3A, an exemplary corner piece 310 is shown that has a groove structure that includes a vertical portion 311 and a horizontal portion 313. In one embodiment, the protrusion 315 of the adjacent and interlocked corner piece is designed to be positioned slightly below the horizontal portion 313 of the groove structure of the exemplary corner piece 310 when the exemplary corner piece 310 and the adjacent corner piece are interlocked. In one embodiment, the module associated with the adjacent and interlocked corner piece can be vertically removed by sliding the module vertically along the vertical portion 311 of the groove structure. In one embodiment, the module associated with the adjacent and interlocked corner piece can be horizontally removed by slightly lifting the module vertically to position the protrusion of the adjacent and interlocked corner piece adjacent to the opening to the horizontal portion 313 of the groove structure and then sliding the module horizontally along the horizontal portion of the groove structure until the module is free. In FIG. 3B, an exemplary corner piece 320 is shown that also has a groove structure that includes a vertical portion 321 and a horizontal portion 323.

In the FIG. 3B embodiment, the protrusion 325 of the adjacent corner piece is designed to be positioned adjacent to the opening to the horizontal portion 323 of the groove structure of the exemplary corner piece 320 when the exemplary corner piece 320 and the adjacent corner piece are interlocked. The opening to the horizontal portion 323 of the groove structure is blocked by a lock 327. In one embodiment, the module associated with the adjacent and interlocked corner piece can be vertically removed by sliding the module vertically along the vertical portion 321 of the groove structure. In one embodiment, the module associated with the adjacent and interlocked corner piece can be horizontally removed by lifting the lock 327 that blocks the opening to the horizontal portion 323 of the groove structure and sliding the module horizontally along the horizontal portion of the groove structure until the module is free. In FIG. 3C, an exemplary corner piece 330 is shown that has a groove structure that includes a vertical portion 331 and a sloped portion 333.

In the FIG. 3C embodiment, the protrusion 335 of the adjacent corner piece is designed to be positioned slightly below the sloped portion 333 of the groove structure of the exemplary corner piece 330 when the exemplary corner piece and the adjacent corner piece are interlocked. In one embodiment, the module associated with the adjacent and interlocked corner piece can be vertically removed by sliding the module vertically along the vertical portion 331 of the groove structure. In one embodiment, the module associated with the adjacent and interlocked corner piece can be removed in an upwardly sloped direction by slightly lifting the module vertically to position the protrusion of the adjacent and interlocked corner piece adjacent to the opening of the sloped portion 333 of the groove structure and then sliding the module along the sloped portion of the groove structure until the module is free.

Referring to FIG. 3D, an exemplary corner piece 340 is shown that has a groove structure that includes a vertical portion 341 and a plurality of horizontal portions 343 and 345. In one embodiment, a plurality of protrusions 347 of the adjacent and interlocked corner piece are designed to be positioned slightly below the horizontal portions 343 and 345 of the groove structure of the exemplary corner piece 340 when the exemplary corner piece 340 and the adjacent corner piece are interlocked. In one embodiment, the module associated with the adjacent and interlocked corner piece can be vertically removed by sliding the module vertically along the vertical portion 341 of the groove structure. In one embodiment, the module associated with the adjacent and interlocked corner piece can be horizontally removed by slightly lifting the module vertically to position the plurality of protrusions 347 of the adjacent and interlocked corner piece adjacent to the opening to the horizontal portions 343 and 345 of the groove structure and then sliding the module horizontally along the horizontal portions 343 and 345 of the groove structure until the module is free.

In FIG. 3E, an exemplary corner piece 350 is shown that also has a groove structure that includes a vertical portion 351 and a plurality of horizontal portions 353 and 355. In the FIG. 3E embodiment, a plurality of protrusions 357 of the adjacent corner piece are designed to be positioned adjacent to the openings to the plurality of horizontal portions 353 and 355 of the groove structure of the exemplary corner piece 350 when the exemplary corner piece 350 and the adjacent corner piece are interlocked. The openings to the plurality of the horizontal portions of the groove structure are blocked by a lock. In one embodiment, the module associated with the adjacent and interlocked corner piece can be vertically removed by sliding the module vertically along the vertical portion 351 of the groove structure. In one embodiment, the module associated with the adjacent and interlocked corner piece can be horizontally removed by lifting the lock 359 that blocks the openings to the plurality of horizontal portions 353 and 355 of the groove structure and sliding the module horizontally along the horizontal portions 353 and 355 of the groove structure until the module is free.

In FIG. 3F, an exemplary corner piece 360 is shown that has a groove structure that includes a vertical portion 361 and a plurality of sloped portions 363 and 365. In the FIG. 3F embodiment, a plurality of protrusions 367 of the adjacent corner piece are designed to be positioned slightly below the plurality of sloped portions 363 and 365 of the groove structure of the exemplary corner piece 360 when the exemplary corner piece 360 and the adjacent corner piece are interlocked. In one embodiment, the module associated with the adjacent and interlocked corner piece can be vertically removed by sliding the module vertically along the vertical portion 361 of the groove structure. In one embodiment, the module associated with the adjacent and interlocked corner piece can be removed in an upwardly sloped direction by slightly lifting the module vertically to position the plurality of protrusions 367 of the adjacent and interlocked corner piece adjacent to the openings of the plurality of sloped portions 363 and 365 of the groove structure and then sliding the module along the sloped portions 363 and 365 of the groove structure until the module is free.

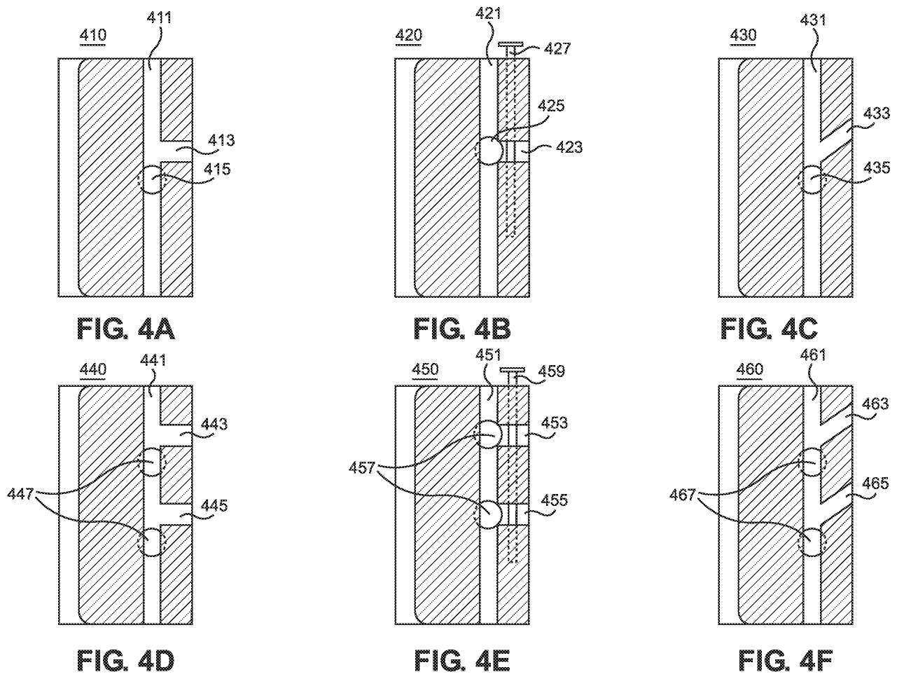

FIGS. 4A-4F show additional protrusion and groove configurations for exemplary module clip pieces according to one embodiment. In one embodiment, the uses of the module clip pieces shown in FIGS. 4A-4F can include use on a single side of a module (or top in some cases) to provide a basic measure of package stability (e.g., for shorter transport), or in the case of the module clip pieces shown in FIGS. 4B and 4E, in combination with other either vertically or horizontally slidable pieces, located at other places on the module frame, to enhance package stability. In FIGS. 4A-4F, a circular representation of a protrusion, that is associated with an adjacent and interlocked module clip piece (other parts of the adjacent and interlocked module clip piece are not shown) is superimposed on the diagrams of the exemplary side pieces. Referring to FIG. 4A, an exemplary module clip pieces 410 is shown that has a groove structure that includes a vertical portion 411 and a horizontal portion 413. In one embodiment, the protrusion 415 of the adjacent and interlocked module clip pieces is designed to be positioned slightly below the horizontal portion 413 of the groove structure of the exemplary module clip piece when the exemplary module clip piece and the adjacent module clip piece are interlocked. In one embodiment, the module associated with the adjacent and interlocked module clip piece can be vertically removed by sliding the module vertically along the vertical portion 411 of the groove structure. In one embodiment, the module associated with the adjacent and interlocked module clip piece can be horizontally removed by slightly lifting the module vertically to position the protrusion 415 of the adjacent and interlocked module clip piece adjacent to the opening to the horizontal portion of the groove structure and then sliding the module horizontally along the horizontal portion 413 of the groove structure until the module is free. In FIG. 4B, an exemplary module clip piece 420 is shown that also has a groove structure that includes a vertical portion 421 and a horizontal portion 423. In the FIG. 4B embodiment, the protrusion 425 of the adjacent module clip piece is designed to be positioned adjacent to the opening to the horizontal portion 423 of the groove structure of the exemplary module clip piece 420 when the exemplary module clip piece 420 and the adjacent side piece are interlocked. The opening to the horizontal portion 423 of the groove structure is blocked by a lock 427. In one embodiment, the module associated with the adjacent and interlocked module clip piece can be vertically removed by sliding the module vertically along the vertical portion 421 of the groove structure. In one embodiment, the module associated with the adjacent and interlocked module clip piece can be horizontally removed by lifting the lock 427 that blocks the opening to the horizontal portion 423 of the groove structure and sliding the module horizontally along the horizontal portion 423 of the groove structure until the module is free. In FIG. 4C, an exemplary module clip piece 430 is shown that has a groove structure that includes a vertical portion 431 and a sloped portion 433. In the FIG. 4C embodiment, the protrusion 435 of the adjacent module clip piece is designed to be positioned slightly below the sloped portion 433 of the groove structure of the exemplary module clip piece when the exemplary module clip piece 430 and the adjacent module clip piece are interlocked. In one embodiment, the module associated with the adjacent and interlocked module clip piece can be vertically removed by sliding the module vertically along the vertical portion 431 of the groove structure. In one embodiment, the module associated with the adjacent and interlocked module clip piece can be removed in an upwardly sloped direction by slightly lifting the module vertically to position the protrusion of the adjacent and interlocked module clip piece adjacent to the opening of the sloped portion 433 of the groove structure and then sliding the module along the sloped portion 433 of the groove structure until the module is free.

Referring to FIG. 4D, an exemplary module clip piece 440 is shown that has a groove structure that includes a vertical portion 441 and a plurality of horizontal portions 443 and 445. In one embodiment, a plurality of protrusions 447 of the adjacent and interlocked module clip piece are designed to be positioned slightly below the horizontal portions 443 and 445 of the groove structure of the exemplary module clip piece 440 when the exemplary module clip piece and the adjacent module clip piece are interlocked. In one embodiment, the module associated with the adjacent and interlocked module clip piece can be vertically removed by sliding the module vertically along the vertical portion 441 of the groove structure. In one embodiment, the module associated with the adjacent and interlocked module clip piece can be horizontally removed by slightly lifting the module vertically to position the plurality of protrusions 447 of the adjacent and interlocked module clip piece adjacent to the openings to the horizontal portions 443 and 445 of the groove structure and then sliding the module horizontally along the horizontal portions 443 and 445 of the groove structure until the module is free. In FIG. 4E, another exemplary module clip piece 450 is shown that has a groove structure that includes a vertical portion 451 and a plurality of horizontal portions 453 and 455. In the FIG. 4E embodiment, a plurality of protrusions 457 of the adjacent module clip piece are designed to be positioned adjacent to the openings to the plurality of horizontal portions 453 and 455 of the groove structure of the exemplary module clip piece 450 when the exemplary module clip piece 450 and the adjacent module clip piece are interlocked. The openings to the plurality of horizontal portions 453 and 455 of the groove structure are blocked by a lock 459. In one embodiment, the module associated with the adjacent and interlocked module clip piece can be vertically removed by sliding the module vertically along the vertical portion 451 of the groove structure. In one embodiment, the module associated with the adjacent and interlocked module clip piece can be horizontally removed by lifting the lock 459 that blocks the openings to the plurality of horizontal portions 453 and 455 of the groove structure and sliding the module horizontally along the horizontal portions 453 and 455 of the groove structure until the module is free. In FIG. 4F, an exemplary module clip piece 460 is shown that has a groove structure that includes a vertical portion 461 and a plurality of sloped portions 463 and 465. In the FIG. 4F embodiment, a plurality of protrusions 467 of the adjacent side/top piece are designed to be positioned slightly below the plurality of sloped portions 463 and 465 of the groove structure of the exemplary module clip piece 460 when the exemplary module clip piece 460 and the adjacent module clip piece are interlocked. In one embodiment, the module associated with the adjacent and interlocked module clip piece can be vertically removed by sliding the module vertically along the vertical portion 461 of the groove structure. In one embodiment, the module associated with the adjacent and interlocked module clip piece can be removed in an upwardly sloped direction by slightly lifting the module vertically to position the plurality of protrusions 467 of the adjacent and interlocked module clip piece adjacent to the openings of the plurality of sloped portions 463 and 465 of the groove structure and then sliding the module along the sloped portions 463 and 465 of the groove structure until the module is free.

### Operation

In operation, when module clip pieces such as corner pieces (V101 in FIG. 1A and H101 in FIG. 1D), side pieces (V201 in FIG. 2A), and top/bottom pieces (H201 in FIG. 2B), have been properly attached to module frames (150 in FIG. 1E) and the module frames interlocked, the module clip pieces act to both restrict the movement of the module frames in a first direction and allow the module frames to be freely moved in a second direction. Moreover, in one embodiment, during the transport of modules (103₁-103n in FIG. 1A) including long distance shipping that includes multiple transits, the interlocked clip pieces such as corner pieces (V101 in FIG. 1A and H101 in FIG. 1D), side pieces (V201 in FIG. 2A), and top/bottom pieces (H201 in FIG. 2B), operate to prevent tilt even in the absence of straps. In one embodiment, because of the interlocked module clip pieces such as corner pieces (V101 in FIG. 1A and H101 in FIG. 1D), side pieces (V201 in FIG. 2A), and top/bottom pieces (H201 in FIG. 2B), the preparation of partial packages, such as for residential product shipment, is straightforward, because a partial quantity of vertically packed modules can be packaged readily from a stable vertical orientation. In addition, when modules (103₁-103n in FIG. 1G) are horizontally stacked (170 in FIG. 1G), the operation of clip pieces such as corner pieces (V101 in FIG. 1A and H101 in FIG. 1D), side pieces (V201 in FIG. 2A), and top pieces (H201 in FIG. 2B), to direct stress away from the modules and prevent damage to the modules, makes the use of horizontal packing a viable packaging option as the quantity of modules that can be packaged is not severely limited by micro-cracks concerns.

In one embodiment, for horizontally packed packages, the corner piece design can be used to facilitate the packaging of up to 30 modules. In other embodiments, for horizontally packed packages, the corner piece design can be used to facilitate the packaging of greater than 30 modules. In one embodiment, because the corner piece design can make horizontal packing a viable packaging option, flipping the horizontally stacked modules (170 in FIG. 1L) becomes unnecessary. In one embodiment, for partial packages prepared at regional warehouses, because more modules can be horizontally packed, more modules can be delivered to customers.

In one embodiment, as described herein, corner pieces (V101 in FIG. 1A) are formed to include a protrusion (V101f in FIG. 1G) on a first side of the corner piece and a groove (V101e in FIG. 1G) on a second side of the corner piece (that correspond, respectively, to the module sunny side and backsheet side). In one embodiment, as part of a production line process, module clip pieces such as corner pieces (V101 in FIG. 1A and H101 in FIG. 1D), side pieces (V201 in FIG. 2A), and top pieces (H201 in FIG. 2B), are attached to individual modules. Thereafter, each of the modules that will be put into a package is horizontally stacked. In one embodiment, the modules can be horizontally stacked by a binning machine. In other embodiments, the modules can be horizontally stacked by other suitable methods of stacking the modules. In one embodiment, during the stacking process, the protrusions of corner pieces attached to a module that has a neighboring module located on the side of the module adjacent the protrusions of the module's clip pieces, will interlock with the grooves of the module clip pieces attached to the neighboring module. In this manner, the module clip pieces such as corner pieces (V101 in FIG. 1A and H101 in FIG. 1D), side pieces (V201 in FIG. 2A), and top/bottom pieces (H201 in FIG. 2B), of the modules in the stack of modules will be bound, or coupled to, other corner pieces, either directly as a neighboring corner piece, indirectly through a neighboring corner piece, and/or indirectly through the module frame. In one embodiment, after the modules have been horizontally stacked (170 in FIG. 1L), a flipping machine can flip the horizontally stacked modules such that they have a vertical orientation. In one embodiment, because of the interlocking of the module clip pieces such as corner pieces (V101 in FIG. 1A and H101 in FIG. 1D), side pieces (V201 in FIG. 2A), and top/bottom pieces (H201 in FIG. 2B), tilting of the now vertically oriented modules is prevented. In embodiments, where vertically slidable module clip pieces are used, because the grooves are open in the vertical direction, to unload modules, the modules can be readily pulled out vertically, as the modules will slide out without difficulty, without the need to remove the whole package, and without the need to find a rigid structure onto which to lean the modules. In embodiments where horizontally slidable clip pieces are used, because the grooves are open in the horizontal direction, to unload modules, the modules can be readily pulled out horizontally, as the modules will slide out along the horizontal grooves without difficulty. In embodiments, where module clip pieces are used that are both vertically and horizontally slidable (FIGS. 3B, 3E, 4B and 4E), because the grooves are open in both the vertical and the horizontal direction, to unload modules, the modules can be readily pulled out vertically or horizontally, as the module will slide out vertically or horizontally without difficulty.

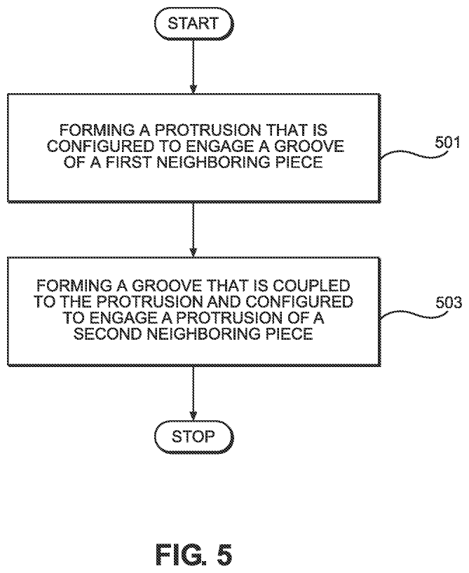

FIG. 5 shows a flowchart of a method of forming a module clip piece such as a corner piece (V101 in FIG. 1A and H101 in FIG. 1D), side piece (V201 in FIG. 2A), and top piece (H201 in FIG. 2B), for a rectangular module according to one embodiment. It should be noted that, in one embodiment, the order of execution of the blocks of the flowchart of FIG. 5 can be changed. Referring to FIG. 5, the method includes at 501, forming at least one protrusion that is configured to engage at least one groove of a first neighboring module clip piece, the at least one protrusion protruding in a first direction. And, at 503, forming at least one groove that is coupled to the at least one protrusion and configured to engage at least one protrusion of a second neighboring module clip piece, the groove extending in a second direction orthogonal to the first direction. In one embodiment, if the module clip piece is a corner piece it can include an L-shaped region that accommodates the corner of a frame of the rectangular module. In one embodiment, the module clip piece can include sidewalls that are configured to restrict movement of the frame. In one embodiment, the module clip piece can include a ridge on at least one of the sidewalls that restricts movement of the frame portion of the rectangular module. As such, the ridge helps fittably couple the frame to the module clip piece. In one embodiment, the protrusion is configured to move along the groove of the first neighboring module clip piece in the second direction. In one embodiment, the groove is configured to prevent movement of the second neighboring module's clip piece in the first direction. In one embodiment, the rectangular module is a solar panel module.

Although specific embodiments have been described above, these embodiments are not intended to limit the scope of the present disclosure, even where only a single embodiment is described with respect to a particular feature. Examples of features provided in the disclosure are intended to be illustrative rather than restrictive unless stated otherwise. The above description is intended to cover such alternatives, modifications, and equivalents as would be apparent to a person skilled in the art having the benefit of the present disclosure.

The scope of the present disclosure includes any feature or combination of features disclosed herein (either explicitly or implicitly), or any generalization thereof, whether or not it mitigates any or all of the problems addressed herein. Thus, the various features of the different embodiments may be variously combined, with some features included, and others excluded to suit a variety of different applications. Accordingly, new claims may be formulated during prosecution of the present application (or an application claiming priority thereto) to any such combination of features. In particular, with reference to the appended claims, features from dependent claims may be combined with those of the independent claims and features from respective independent claims may be combined in any appropriate manner and not merely in the specific combinations enumerated in the appended claims.

What is claimed is:

1. A module clip piece, comprising:
at least one protrusion configured to engage at least one groove of a first neighboring module clip piece, the at least one protrusion protruding in a first direction; and
at least one groove coupled to the at least one protrusion and configured to engage at least one protrusion of a second neighboring module clip piece, the at least one groove extending in a second direction orthogonal to the first direction.

2. The module clip piece of claim 1, wherein the at least one protrusion is configured to move along the at least one groove of the first neighboring module clip piece in the second direction.

3. The module clip piece of claim 1, wherein the at least one groove is configured to prevent movement of the second neighboring module clip piece in the first direction.

4. The module clip piece of claim 1, wherein the at least one groove includes grooves that extend in different directions.

5. The module clip piece of claim 4, further comprising sidewalls that restrict movement of a module frame.

6. The module clip piece of claim 4, further comprising a ridge that restricts movement of a module frame.

7. The module clip piece of claim 1, wherein the module is a solar panel module.

8. A corner piece for a module, comprising:
a protrusion configured to engage a groove of a first neighboring corner piece, the protrusion protruding in a first direction; and
a groove coupled to the protrusion and configured to engage a protrusion of a second neighboring corner piece, the groove extending in a second direction orthogonal to the first direction.

9. The corner piece for a module of claim 8, wherein the protrusion is configured to move along the groove of the first neighboring corner piece in the second direction.

10. The corner piece for a module of claim 8, wherein the groove is configured to prevent movement of the second neighboring corner piece in the first direction.

11. The corner piece for a module of claim 8, further comprising an L-shaped region that accommodates the corner of a frame of the module.

12. The corner piece for a module of claim 11, further comprising sidewalls that restrict movement of the frame.

13. The corner piece for a module of claim 11, further comprising a ridge that restricts movement of the frame.

14. The corner piece for a module of claim 8, wherein the module is a solar panel module.

15. A package of rectangular modules, comprising:
a plurality of rectangular modules; and
module clip pieces attached to the plurality of rectangular modules,
wherein the module clip pieces comprise:
at least one protrusion configured to engage at least one groove of a first neighboring module clip piece, the at least one protrusion protruding in a first direction; and
at least one groove coupled to the at least one protrusion and configured to engage at least one protrusion of a second neighboring module clip piece, the at least one groove extending in a second direction orthogonal to the first direction.

16. The package of rectangular modules of claim 15, wherein the at least one protrusion is configured to move along the at least one groove of the first neighboring module clip piece in the second direction.

17. The package of rectangular modules of claim 15, wherein the at least one groove is configured to prevent movement of the second neighboring module clip piece in the first direction.

18. The package of rectangular modules of claim 15, wherein the at least one groove includes grooves that are directed in different angles.

19. The package of rectangular modules of claim 18, wherein the module clip pieces further comprise sidewalls that restrict movement of a module frame.

20. The package of rectangular modules of claim 18, wherein the module clip pieces further comprise a ridge that restricts movement of a module frame.
